(19) United States
(12) Patent Application Publication
(10) Pub. No.: US 2023/0268434 A1
(43) Pub. Date: Aug. 24, 2023

(54) NITRIDE SEMICONDUCTOR DEVICE AND MANUFACTURING METHOD OF NITRIDE SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Kazuki IKEYAMA, Nisshin-shi (JP)

(21) Appl. No.: 18/153,554

(22) Filed: Jan. 12, 2023

(30) Foreign Application Priority Data
Feb. 21, 2022 (JP) 2022-024835

(51) Int. Cl. H01L 29/78; H01L 21/266; H01L 29/20

(52) U.S. Cl. CPC H01L 29/7813; H01L 21/266; H01L 29/2003

(57) ABSTRACT

A nitride semiconductor device includes a drift region, a body region, a source region, an insulated gate, and a source electrode. The drift region has a first conductivity type and is made of a nitride semiconductor. The body region has a second conductivity type, is made of a nitride semiconductor, and is disposed on the drift region. The source region has the first conductivity type and is separated from the drift region by the body region. The insulated gate faces a portion of the body region that is located between the drift region and the source region. The source electrode is electrically connected to the body region and the source region. The source region is made of a deposited film.

### CROSS REFERENCE TO RELATED APPLICATION

The present application claims the benefit of priority from Japanese Patent Application No. 2022-024835 filed on Feb. 21, 2022. The entire disclosure of the above application is incorporated herein by reference.

### TECHNICAL FIELD

The present disclosure relates to a nitride semiconductor device and a manufacturing method of a nitride semiconductor device.

### BACKGROUND

There has been known a manufacturing method of a nitride semiconductor device that includes implanting n-type impurity ions in a p-type body region to form an n-type source region.

### SUMMARY

The present disclosure provides a nitride semiconductor device that includes a drift region, a body region, a source region, an insulated gate, and a source electrode, and the source region is made of a deposited film. The present disclosure further provides a manufacturing method of a nitride semiconductor device that includes deposing a source region on a body region after releasing hydrogen from the body region.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view illustrating a main part of a nitride semiconductor device according to a first embodiment;

FIG. 2 is a cross-sectional view illustrating a process of manufacturing the nitride semiconductor device according to the first embodiment;

FIG. 3 is a cross-sectional view illustrating a process of manufacturing the nitride semiconductor device according to the first embodiment, subsequent to the process illustrated in FIG. 2;

FIG. 4 is a cross-sectional view illustrating a process of manufacturing the nitride semiconductor device according to the first embodiment, subsequent to the process illustrated in FIG. 3;

FIG. 5 is a cross-sectional view illustrating a process of manufacturing the nitride semiconductor device according to the first embodiment, subsequent to the process illustrated in FIG. 4;

FIG. 6 is a cross-sectional view illustrating a process of manufacturing the nitride semiconductor device according to the first embodiment, subsequent to the process illustrated in FIG. 5;

FIG. 7 is a cross-sectional view illustrating a main part of a nitride semiconductor device according to a second embodiment;

FIG. 8 is a cross-sectional view illustrating a process of manufacturing the nitride semiconductor device according to the second embodiment;

FIG. 9 is a cross-sectional view illustrating a process of manufacturing the nitride semiconductor device according to the second embodiment, subsequent to the process illustrated in FIG. 8;

FIG. 10 is a cross-sectional view illustrating a process of manufacturing the nitride semiconductor device according to the second embodiment, subsequent to the process illustrated in FIG. 9;

FIG. 11 is a cross-sectional view illustrating a process of manufacturing the nitride semiconductor device according to the second embodiment, subsequent to the process illustrated in FIG. 10;

FIG. 12 is a cross-sectional view illustrating a process of manufacturing the nitride semiconductor device according to the second embodiment, subsequent to the process illustrated in FIG. 11;

FIG. 13 is a cross-sectional view illustrating a process of manufacturing the nitride semiconductor device according to the second embodiment, subsequent to the process illustrated in FIG. 12; and

FIG. 14 is a cross-sectional view illustrating a process of manufacturing the nitride semiconductor device according to the second embodiment, subsequent to the process illustrated in FIG. 13.

### DETAILED DESCRIPTION

When an n-type source region is formed in a p-type body region of a nitride semiconductor device, an ion implantation technique can be used. However, when the n-type source region is formed using the ion implantation technique, an activation rate of the n-type source region is low due to mixture of defects formed during ion implantation and p-type impurities (for example, magnesium).

A nitride semiconductor device according to an aspect of the present disclosure includes a drift region, a body region, a source region, an insulated gate, and a source electrode. The drift region has a first conductivity type and is made of a nitride semiconductor. The body region has a second conductivity type, is made of a nitride semiconductor, and is disposed on the drift region. The source region has the first conductivity type and is separated from the drift region by the body region. The insulated gate faces a portion of the body region that is located between the drift region and the source region. The source electrode is electrically connected to the body region and the source region. The source region is made of a deposited film.

In the above-described nitride semiconductor device, the source region is made of the deposited film. Therefore, in the source region, mixture of defects formed during ion implantation and second conductivity type impurities in the body region does not occur. The source region can have a high activation rate. Note that a method of forming the deposited film referred to here is not particularly limited, and various deposition techniques such as chemical vapor deposition (CVD) and physical vapor deposition (PVD) can be used.

A manufacturing method of a nitride semiconductor device according to another aspect of the present disclosure includes: depositing a body region on a drift region, the drift region having a first conductivity type and made of a nitride semiconductor, the body region having a second conductivity type and made of a nitride semiconductor; releasing hydrogen from the body region by performing a dehydrogenation annealing treatment; depositing a source region of the first conductivity type on the body region after the releasing of hydrogen from the body region; forming an insulated gate to face a portion of the body region that is located between the drift region and the source region; and forming a source electrode that is electrically connected to the body region and the source region.

According to this manufacturing method, the source region is made of the deposited film. Therefore, in the source region, mixture of defects formed during ion implantation and second conductivity type impurities in the body region does not occur. The source region can have a high activation rate. Further, according to this manufacturing method, the source region is deposited after hydrogen is released from the body region. Since hydrogen can be sufficiently released from the body region, the body region can have a high activation rate. Therefore, this manufacturing method can manufacture the nitride semiconductor device having the source region and the body region with the high activation rate.

Hereinafter, embodiments of the present disclosure will be described with reference to accompanying drawings.

### First Embodiment

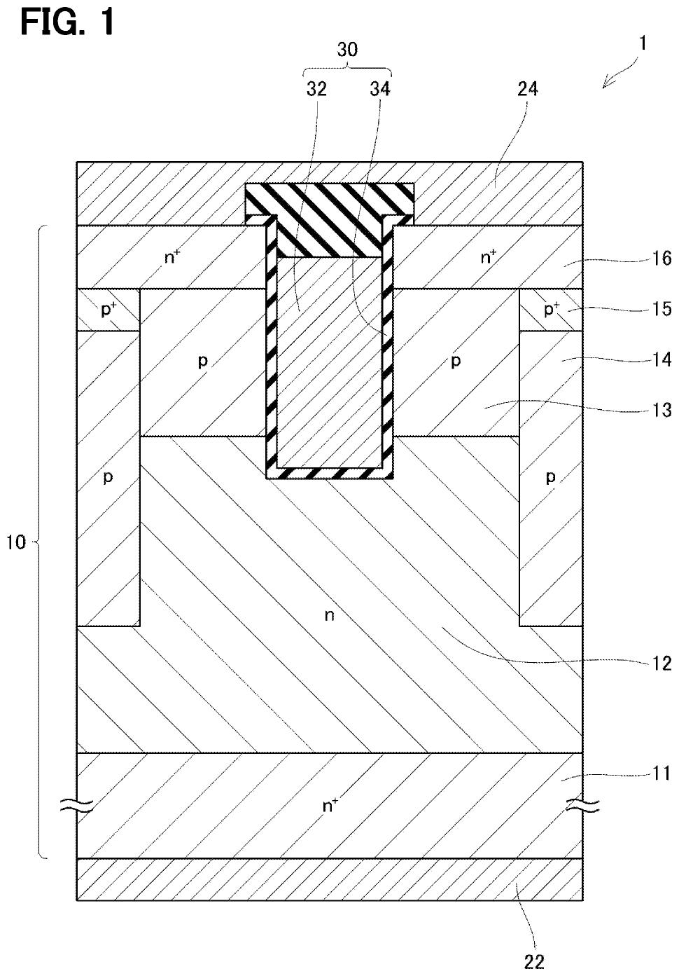

As illustrated in FIG. 1, a nitride semiconductor device 1 according to a first embodiment of the present disclosure is a type of semiconductor device called an n-channel type metal oxide semiconductor field effect transistor (MOSFET). The nitride semiconductor device 1 includes a semiconductor layer 10, a drain electrode 22 covering a lower surface of the semiconductor layer 10, a source electrode 24 covering an upper surface of the semiconductor layer 10, and a trench gate 30 provided in an upper layer portion of the semiconductor layer 10. The semiconductor layer 10 includes an n⁺-type drain region 11, an n-type drift region 12, a p-type body region 13, a p-type electric field relaxation region 14, a p⁺-type body contact region 15, and an n⁺-type source region 16. N-type impurities contained in the semiconductor layer 10 are not particularly limited, but may be silicon (Si), for example. P-type impurities contained in the semiconductor layer 10 are not particularly limited, but may be magnesium (Mg), for example.

The drain region 11 is provided in a lower layer portion of the semiconductor layer 10 and contains n-type impurities at a high concentration. The drain region 11 is exposed on the lower surface of the semiconductor layer 10 and is in ohmic contact with the drain electrode 22. The drain region 11 is prepared as an n-type GaN substrate, as will be described later, and is also a base substrate for crystal growth of the drift region 12 and the body region 13.

The drift region 12 is disposed above the drain region 11 and is in contact with an upper surface of the drain region 11. The drift region 12 is disposed between drain region 11 and the body region 13 to separate the drain region 11 and the body region 13. The drift region 12 is in contact with a bottom surface and a part of a lower end of a side surface of the trench gate 30. The drift region 12 has an n-type impurity concentration that is lower than an n-type impurity concentration of the drain region 11. The drift region 12 is made of a nitride semiconductor, and is not particularly limited, but may be made of gallium nitride, for example.

The body region 13 is disposed above the drift region 12 and is in contact with an upper surface of the drift region 12. The body region 13 is disposed between the drift region 12 and the source region 16 to separate the drift region 12 and the source region 16. The body region 13 is in contact with the side surface of the trench gate 30. The body region 13 is made of a nitride semiconductor, and is not particularly limited, but may be made of gallium nitride, for example.

The electric field relaxation region 14 is disposed to protrude from the body region 13 into the drift region 12 and extends to a position deeper than the bottom surface of the trench gate 30. The electric field relaxation region 14 is disposed apart from the trench gate 30 in one direction parallel to a plane direction of the semiconductor layer 10. A p-type impurity concentration of the electric field relaxation region 14 is not particularly limited, but may be approximately the same as a p-type impurity concentration of the body region 13, for example. The electric field relaxation region 14 is made of a nitride semiconductor, and is not particularly limited, but may be made of gallium nitride, for example.

The body contact region 15 is disposed above the electric field relaxation region 14 and is in contact with a side surface of the body region 13 and an upper surface of the electric field relaxation region 14. The body contact region 15 has a p-type impurity concentration that is higher than the p-type impurity concentrations of the body region 13 and the electric field relaxation region 14. The body contact region 15 is made of a nitride semiconductor, and is not particularly limited, but may be made of gallium nitride, for example. As will be described later, the body contact region 15 is substantially in ohmic contact with the source region 16 by tunneling, and is substantially in ohmic contact with the source electrode 24 via the source region 16.

The source region 16 is disposed above the body region 13 and the body contact region 15 and is in contact with upper surfaces of the body region 13 and the body contact region 15. The source region 16 is disposed in the upper layer portion of the semiconductor layer 10. The source region 16 is interposed between the body region 13 and the source electrode 24 and between the body contact region 15 and the source electrode 24 to separate the body region 13 and the body contact region 15 from the source electrode 24. The source region 16 is in contact with a part of an upper end of the side surface of the trench gate 30. The source region 16 is exposed on the upper surface of the semiconductor layer 10 and is in ohmic contact with the source electrode 24. The source region 16 is made of a nitride semiconductor, and is not particularly limited, but may be made of gallium nitride, for example. The source region 16 may be other nitride semiconductor such as indium gallium nitride (InGaN), aluminum gallium nitride (AlGaN), or indium aluminum gallium nitride (InAIGaN) instead of gallium nitride. The source region 16 may also be made of other semiconductor materials having electron affinities close to 4.1 eV of gallium nitride, such as rhombohedral indium tin oxide (rh-ITO) and bixbite indium tin oxide (bcc-ITO).

The source region 16 has a carrier concentration of 1×10¹⁹ cm⁻³ or higher. Since the carrier concentration of the source region 16 is sufficiently high, the source region 16 and the body contact region 15 are substantially in ohmic contact due to tunneling. Even if the source region 16 is made of indium tin oxide, if the carrier concentration of the source region 16 is sufficiently high, the source region 16 and the body contact region 15 can be in substantial ohmic contact due to the tunneling.

The trench gate 30 extends from the upper surface of the semiconductor layer 10 through the source region 16 and the body region 13 to reach the drift region 12, and has a gate electrode 32 and a gate insulating film 34. The gate electrode 32 faces the drift region 12, the body region 13, and the source region 16 with the gate insulating film 34 interposed therebetween.

Next, the operation of the nitride semiconductor device 1 will be described. When a voltage that is more positive than the source electrode 24 is applied to the drain electrode 22 and a voltage higher than the threshold voltage is applied to the gate electrode 32, the nitride semiconductor device 1 is turned on. At this time, a channel (inversion layer) is formed in a portion of the body region 13 between the drift region 12 and the source region 16 that faces the trench gate 30. Electrons injected from the source region 16 move to the drift region 12 through the channel, flow vertically through the drift region 12, and reach the drain region 11. This flow of the electrons establishes electric continuity between the drain electrode 22 and the source electrode 24, so that the nitride semiconductor device 1 is turned on. When the voltage applied to gate electrode 32 falls below the threshold voltage, the channel disappears and the nitride semiconductor device 1 is turned off.

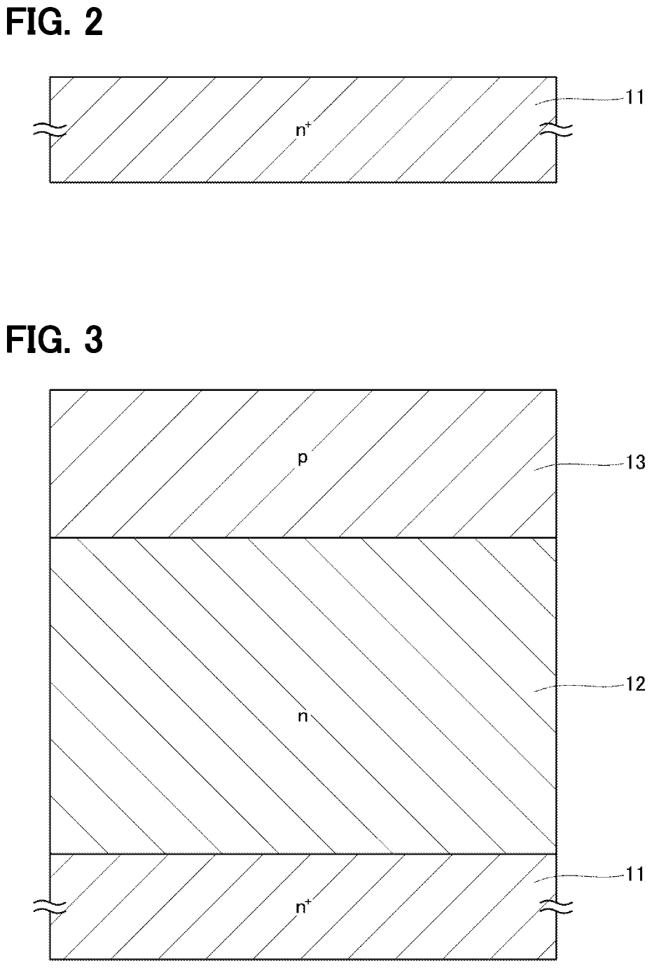

Next, a manufacturing method of the nitride semiconductor device 1 will be described with reference to FIG. 2 to FIG. 6. First, as illustrated in FIG. 2, the drain region 11 that is an n-type GaN substrate is prepared. Next, as illustrated in FIG. 3, crystal growth of the drift region 12 of n-type GaN and the body region 13 of p-type GaN is performed from the upper surface of the drain region 11 in this order using metal organic chemical vapor deposition (MOCVD), for example.

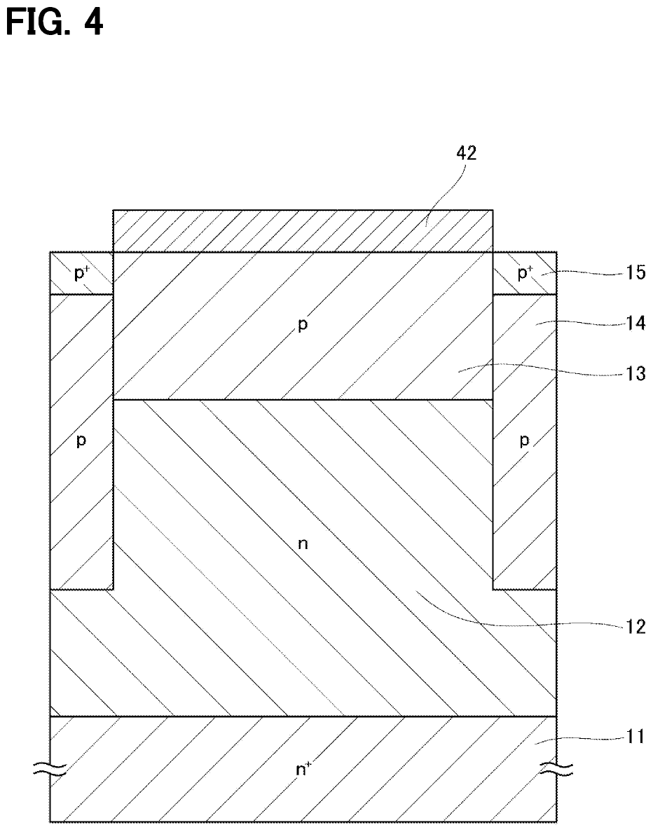

Next, as illustrated in FIG. 4, a mask 42 is deposited on the upper surface of the body region 13. The mask 42 is opened so that a part of the upper surface of the body region 13 is exposed. Next, using an ion implantation technique, p-type impurity ions (magnesium ions in this example) are implanted by channeling implantation through the opening of the mask 42 to form the electric field relaxation region 14 that protrudes from the body region 13 into the drift region 12. Next, using the ion implantation technique, p-type impurity ions (magnesium ions in this example) are randomly implanted through the opening of the mask 42 to form the body contact regions 15 in the upper layer portion of the body region 13. After the ion implantation is finished, the mask 42 is removed.

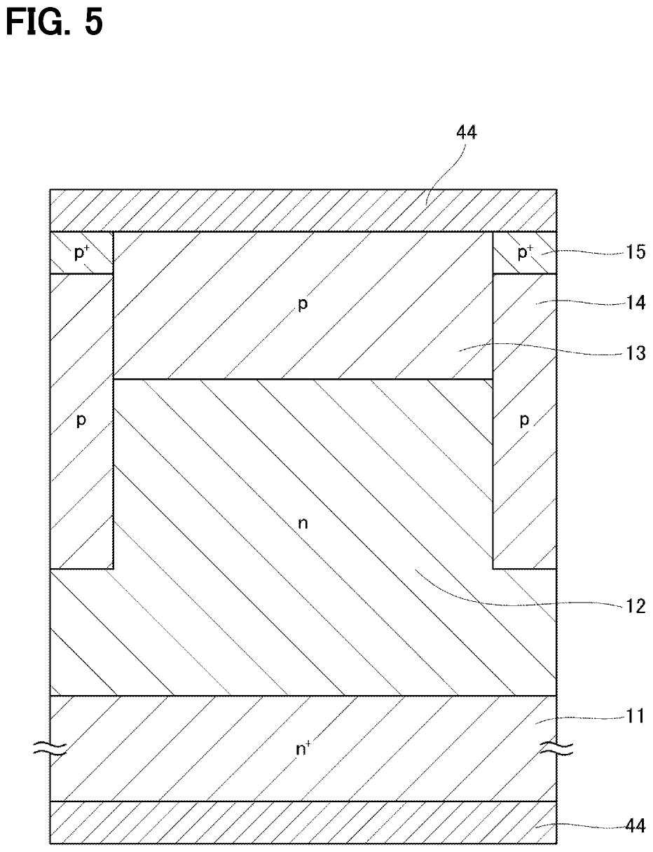

Next, as illustrated in FIG. 5, a protective film 44 is formed on the upper surfaces of the body region 13 and the body contact region 15. The protective film 44 is also formed on the lower surface of the drain region 11. The protective film 44 is used for suppressing release of nitrogen from the upper surfaces of the body region 13 and the body contact region 15 and the lower surface of the drain region 11 during dehydrogenation and activation annealing, which will be described later. The material of the protective film 44 is not particularly limited, but may be aluminum nitride (AlN), for example. Next, a dehydrogenation and activation annealing treatment is performed. The annealing temperature is not particularly limited, but may be, for example, 800° C. or higher. As described above, when the body region 13 is formed using the deposition technique, the body region 13 contains a high concentration of hydrogen derived from the material (for example, Cp2Mg) for adding magnesium, which is a p-type impurity. This hydrogen inhibits the activation of magnesium. When the dehydrogenation and activation annealing treatment is performed, hydrogen is released from the body region 13. In this example, the concentration of hydrogen contained in the body region 13 is reduced to 1×10¹⁸ cm⁻³ or less by the dehydrogenation and activation annealing treatment. Accordingly, magnesium contained in the body region 13 can be favorably activated. After the dehydrogenation and activation annealing treatment is completed, the protective film 44 is removed.

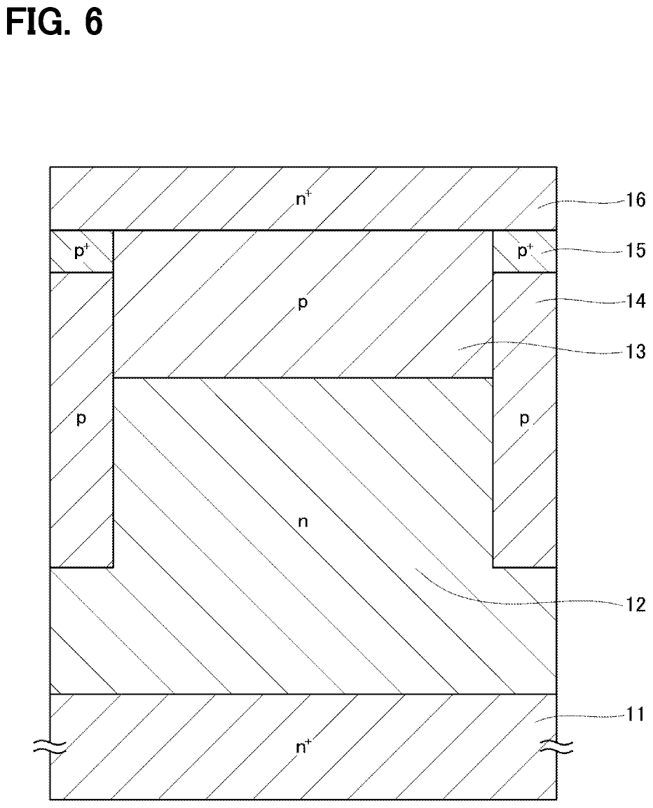

Next, as illustrated in FIG. 6, a crystal growth of the source region 16 made of n-type GaN is performed from the upper surfaces of the body region 13 and the body contact region 15 using, for example, a metal-organic chemical vapor deposition method. The crystal growth of the source region 16 is performed so that the source region 16 has a carrier concentration of 1×10¹⁹ cm⁻³ or higher.

Then, the trench gate 30 is formed using a known manufacturing technique. After that, the drain electrode 22 is formed on the lower surface of the semiconductor layer 10, and the source electrode 24 is formed on the upper surface of the semiconductor layer 10. Accordingly, the nitride semiconductor device 1 illustrated in FIG. 1 is completed.

The above-described manufacturing method of the nitride semiconductor device 1 has at least the following advantages. (1) In the above-described manufacturing method, the source region 16 is formed using a deposition technique. Therefore, defects in the source region 16 are less than when the source region 16 is formed using an ion implantation technique. Therefore, the nitride semiconductor device 1 can have a low on-resistance. Also, defects in the body region 13 below the source region 16 are less than when the source region 16 is formed using the ion implantation technique. For example, a defect density of the body region 13 is reduced to 1×10¹⁶ cm⁻³ or less. Therefore, the nitride semiconductor device 1 has a low trap level density, and threshold fluctuation can be restricted. (2) In the above-described manufacturing method, the source region 16 is formed between the body contact region 15 and the source electrode 24. The body contact region 15 is not in contact with the source electrode 24. In conventional techniques, a metal electrode with a large work function (nickel, gold, and the like) is often interposed between the body contact region 15 and the source electrode 24 in order to make ohmic contact between the p-type body contact region 15 and the metal source electrode 24. The nitride semiconductor device 1 does not require such a metal electrode. (3) In the above-described manufacturing method, the source region 16 is formed after the dehydrogenation and activation annealing treatment is performed. Since the source region 16 is not present on the surface of the body region 13 during the dehydrogenation and activation annealing treatment, hydrogen can be effectively released from the body region 13. As a result, the body region 13 can have a high activation rate.

### Second Embodiment

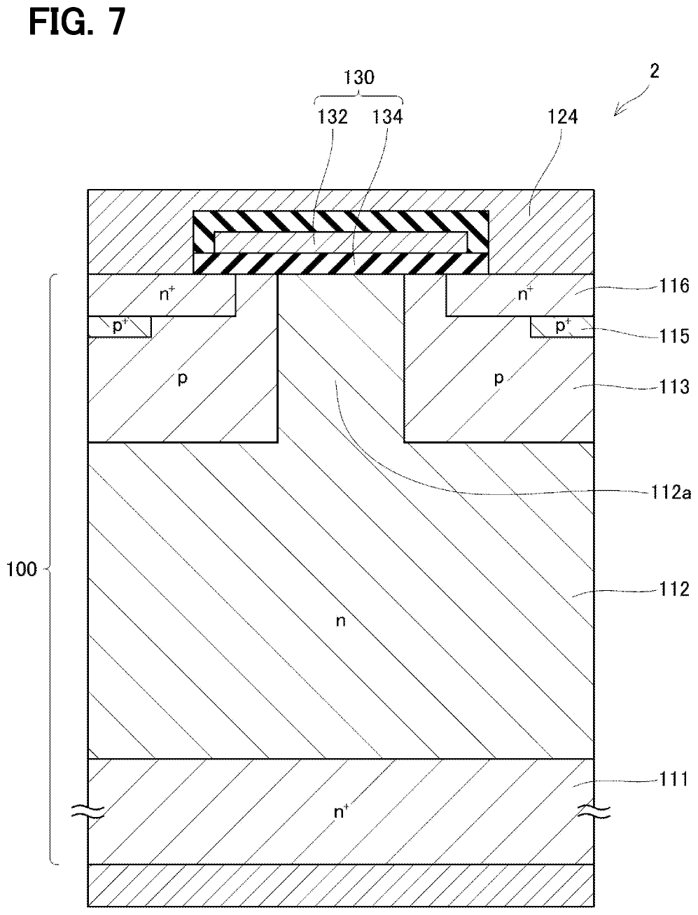

As illustrated in FIG. 7, a nitride semiconductor device 2 according to a second embodiment of the present disclosure is a type of semiconductor device called an n-channel MOSFET. The nitride semiconductor device 2 includes a semiconductor layer 100, a drain electrode 122 covering a lower surface of the semiconductor layer 100, a source electrode 124 covering an upper surface of the semiconductor layer 100, and a planar gate 130 disposed on the upper surface of the semiconductor layer 100. The semiconductor layer 100 includes an n⁺-type drain region 111, an n-type drift region 112, a p-type body region 113, a p⁺-type body contact region 115, and an n⁺-type source region 116. N-type impurities contained in the semiconductor layer 100 are not particularly limited, but may be silicon (Si), for example. P-type impurities contained in the semiconductor layer 100 are not particularly limited, but may be magnesium (Mg), for example.

The drain region 111 is provided in a lower layer portion of the semiconductor layer 100 and contains n-type impurities at a high concentration. The drain region 111 is exposed on the lower surface of the semiconductor layer 100 and is in ohmic contact with the drain electrode 122. The drain region 111 is prepared as an n-type GaN substrate and is also a base substrate for crystal growth of the drift region 112, as will be described later.

The drift region 112 is disposed above the drain region 111 and is in contact with an upper surface of drain region 111. The drift region 112 is disposed between drain region 111 and the body region 113 to separate the drain region 111 and the body region 113. The drift region 112 has an n-type impurity concentration that is lower than an n-type impurity concentration of the drain region 111. The drift region 112 is made of a nitride semiconductor, and is not particularly limited, but may be made of gallium nitride, for example.

The drift region 112 has a JFET region 112a sandwiched between the body regions 113 in one direction parallel to the plane direction of the semiconductor layer 100. The JFET region 112a extends from the surface of the semiconductor layer 100 through the body region 113. The JFET region 112a is in contact with a portion of the bottom surface of planar gate 130.

The body region 113 is disposed above the drift region 112 and is in contact with an upper surface of the drift region 112. The body region 113 is also disposed adjacent to the JFET region 112a of the drift region 112 and is in contact with a side surface of the JFET region 112a. The body region 13 is disposed between the JFET region 112a of the drift region 112 and the source region 116 to separate JFET region 112a of the drift region 112 and the source region 116. The body region 113 is in contact with another portion of the bottom surface of planar gate 130. The body region 113 is made of a nitride semiconductor, and is not particularly limited, but may be made of gallium nitride, for example.

The body contact region 115 is disposed above the body region 113 and is in contact with the upper surface of body region 113. The body contact region 115 has a p-type impurity concentration that is higher than a p-type impurity concentration of the body region 113. The body contact region 115 is made of a nitride semiconductor, and is not particularly limited, but may be made of gallium nitride, for example. As will be described later, the body contact region 115 is substantially in ohmic contact with the source region 116 by tunneling, and is substantially in ohmic contact with the source electrode 124 via the source region 116.

The source region 116 is disposed above the body region 113 and the body contact region 115 and is in contact with upper surfaces of the body region 113 and the body contact region 115. The source region 116 is disposed in the upper layer portion of the semiconductor layer 100. The source region 116 is interposed between the body region 113 and the source electrode 124 and between the body contact region 115 and the source electrode 124 to separate the body region 113 and the body contact region 115 from the source electrode 124. The source region 116 is in contact with another portion of the bottom surface of planar gate 130. The source region 116 is exposed on the upper surface of the semiconductor layer 100 and is in ohmic contact with the source electrode 124. The source region 116 is made of a nitride semiconductor, and is not particularly limited, but may be made of gallium nitride, for example. The source region 116 may be made of other nitride semiconductor such as indium gallium nitride (InGaN), aluminum gallium nitride (AlGaN), or indium aluminum gallium nitride (InAIGaN) instead of gallium nitride. The source region 116 may also be made of other semiconductor materials having electron affinities close to 4.1 eV of gallium nitride, such as rhombohedral indium tin oxide (rh-ITO) and bixbite indium tin oxide (bcc-ITO).

The source region 16 has a carrier concentration of 1×10¹⁹ cm⁻³ or higher. Since the carrier concentration of the source region 116 is sufficiently high, the source region 116 and the body contact region 115 are substantially in ohmic contact due to tunneling. Even if the source region 116 is made of indium tin oxide, if the carrier concentration of the source region 116 is sufficiently high, the source region 116 and the body contact region 115 can be in substantial ohmic contact due to the tunneling.

The planar gate 130 is disposed on the upper surface of the semiconductor layer 100. The planar gate 130 extends from a portion of the source region 116 over the body region 113 to reach the JFET region 112a of the drift region 112. The planar gate 130 includes a gate electrode 132 and gate insulating film 134. The gate electrode 132 faces the JFET region 112a of the drift region 112, the body region 113, and source region 116 with the gate insulating film 134 interposed therebetween.

Next, the operation of the nitride semiconductor device 2 will be described. When a voltage that is more positive than the source electrode 124 is applied to the drain electrode 122 and a voltage higher than the threshold voltage is applied to the gate electrode 132, the nitride semiconductor device 2 is turned on. At this time, a channel (inversion layer) is formed in a portion of the body region 113 facing the planar gate 130 and located between the JFET region 112a of the drift region 112 and the source region 116. Electrons injected from the source region 116 move through the channel to the JFET region 112a of the drift region 112 and flow vertically through the drift region 112 to reach the drain region 111. This flow of the electrons establishes electric continuity between the drain electrode 122 and the source electrode 124, so that the nitride semiconductor device 2 is turned on. When the voltage applied to gate electrode 132 falls below the threshold voltage, the channel disappears and the nitride semiconductor device 2 is turned off.

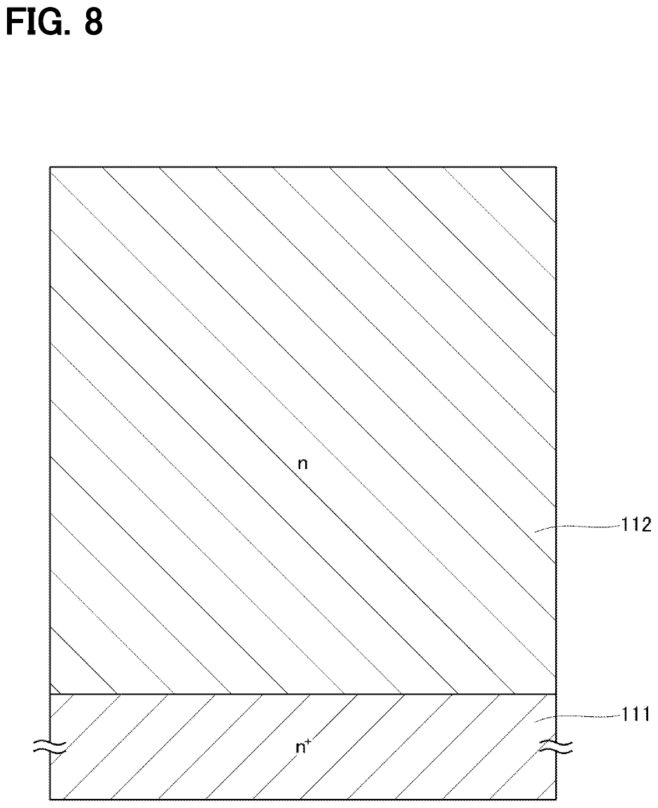

Next, a manufacturing method of the nitride semiconductor device 2 will be described with reference to FIG. 8 to FIG. 14. First, as illustrated in FIG. 8, crystal growth of the drift region 112 is performed from the upper surface of the drain region 111, which is an n-type GaN substrate, using, for example, a metal-organic chemical vapor deposition method.

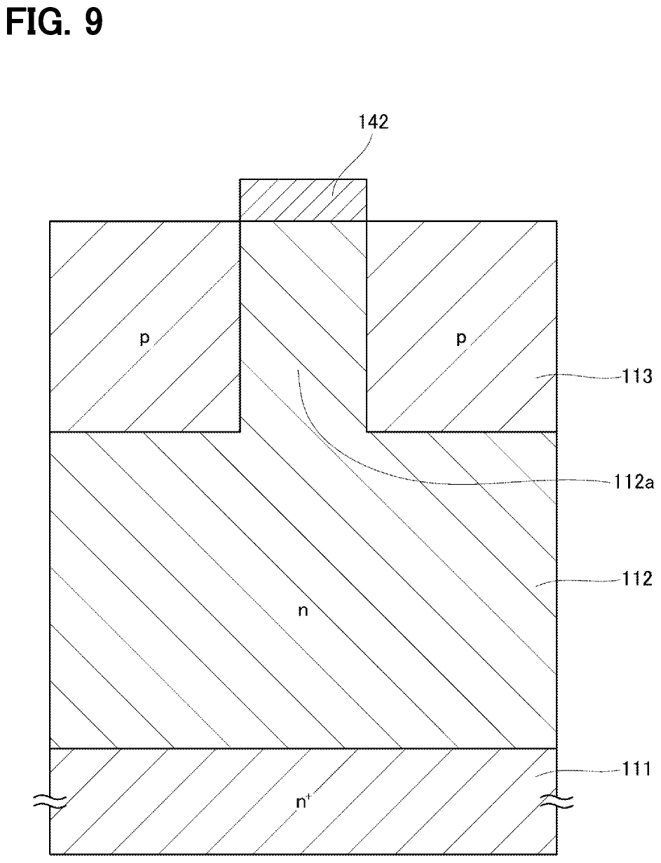

Next, as illustrated in FIG. 9, a mask 142 is deposited on the upper surface of the drift region 112. The mask 142 is opened so that a part of the upper surface of drift region 112 is exposed. Next, using an ion implantation technique, p-type impurity ions (magnesium ions in this example) are implanted through the opening of the mask 142 to form the body region 113. A portion of the drift region 112 sandwiched between the body regions 113 becomes the JFET region 112a. After the ion implantation is finished, the mask 42 is removed.

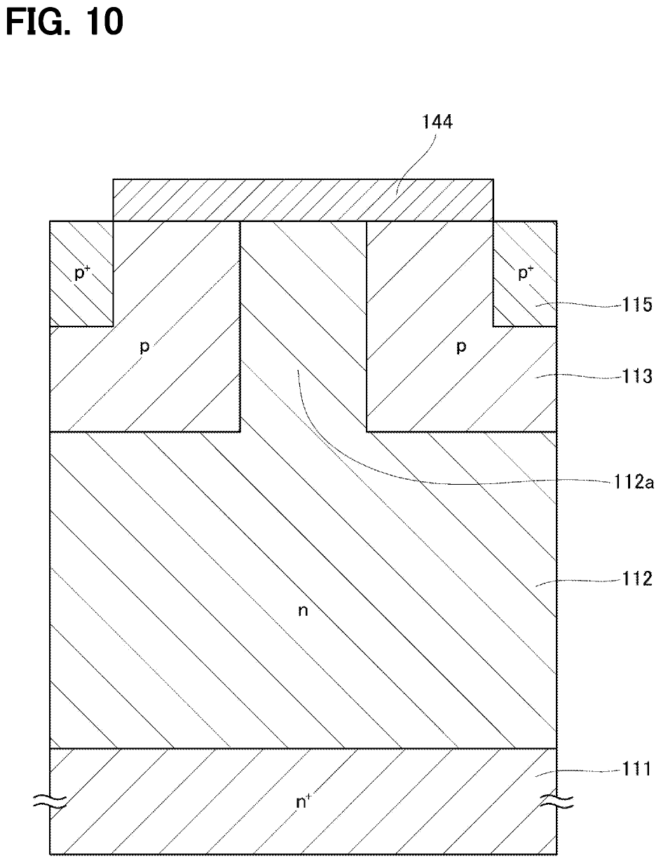

Next, as illustrated in FIG. 10, a mask 144 is deposited on the upper surfaces of the JFET region 112a of the drift region 112 and the body region 113. The mask 144 is opened so that a part of the upper surface of the body region 113 is exposed. Next, using an ion implantation technique, p-type impurity ions (magnesium ions in this example) are implanted through the opening of the mask 144 to form the body contact region 115. After the ion implantation is finished, the mask 144 is removed.

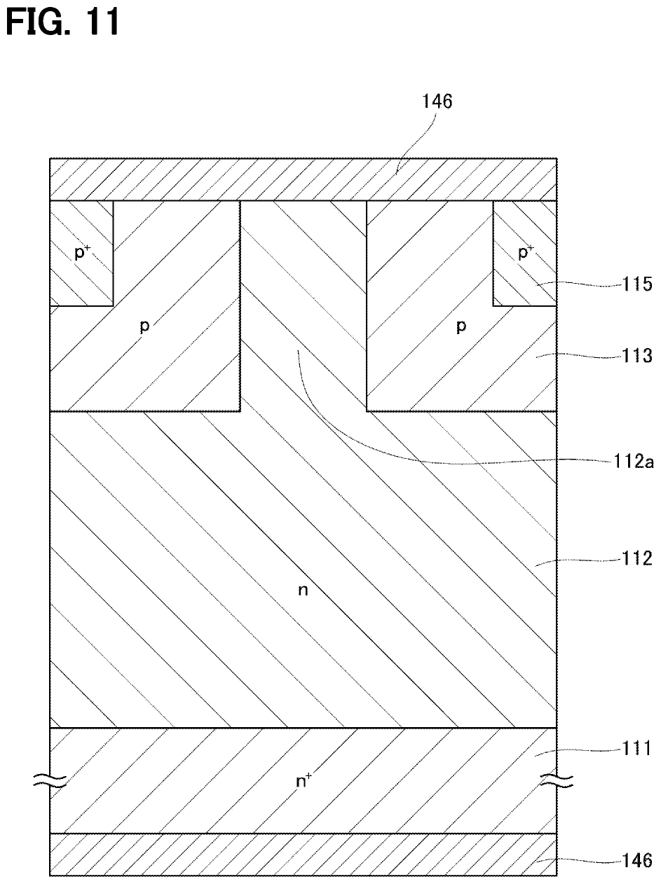

Next, as illustrated in FIG. 11, a protective film 146 is formed on the upper surfaces of the JFET region 112a of the drift region 112, the body region 113, and the body contact region 115. The protective film 44 is also formed on the lower surface of the drain region 111. The material of the protective film 146 is not particularly limited, but may be aluminum nitride (AlN), for example. Next, an activation annealing treatment is performed. The annealing temperature is not particularly limited, but may be, for example, 800° C. or higher. After the activation annealing treatment is finished, the protective film 146 is removed.

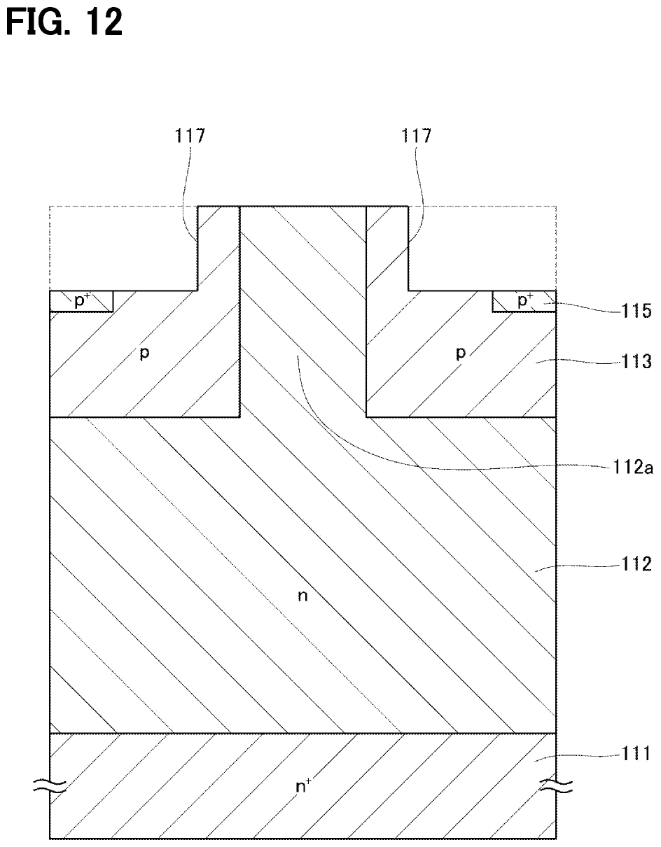

Next, as illustrated in FIG. 12, a dry etching technique is used to partially remove the body region 113 and the body contact region 115 to form a groove having such a depth that a portion of the body contact region 115 remains.

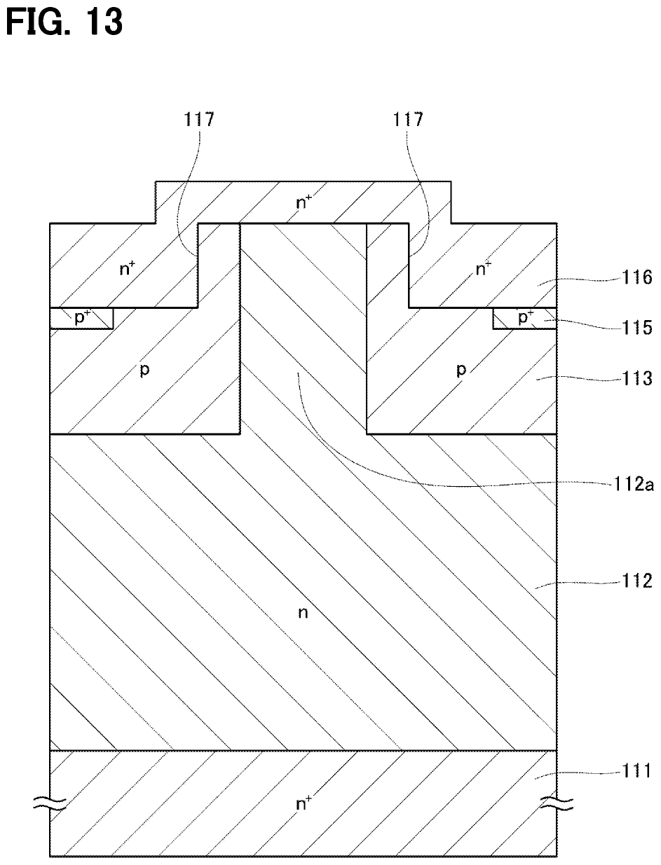

Next, as illustrated in FIG. 13, crystal growth of the source region 116 made of n-type GaN is performed so as to fill the groove 117 using, for example, a metal-organic chemical vapor deposition method. The source region 116 is also deposited on the upper surfaces of the JFET region 112a of the drift region 112 and the body region 113 in a protruding portion sandwiched by the grooves 117.

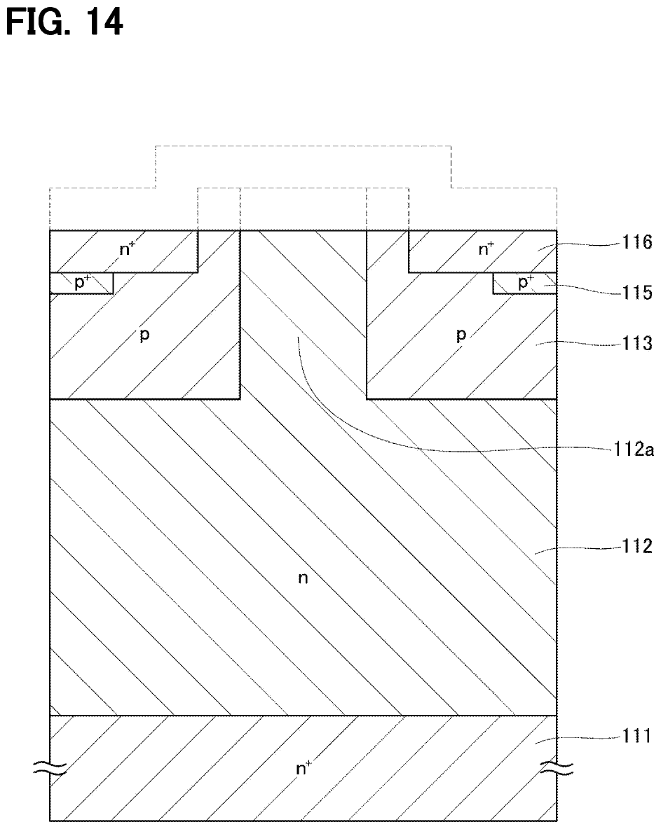

Next, as illustrated in FIG. 14, chemical mechanical polishing (CMP) is used to remove a portion of the source region 116 to expose the JFET region 112a of the drift region 112 and the body region 113 in the protruding portion.

Then, the planar gate 130 is formed using a known manufacturing technique. After that, the drain electrode 122 is formed on the lower surface of the semiconductor layer 100, and the source electrode 124 is formed on the upper surface of the semiconductor layer 100. Accordingly, the nitride semiconductor device 2 illustrated in FIG. 7 is completed.

The above-described manufacturing method of the nitride semiconductor device 2 has at least the following advantages. (1) In the above-described manufacturing method, the source region 116 is formed using a deposition technique. Therefore, defects in the source region 116 are less than when the source region 116 is formed using an ion implantation technique. Therefore, the nitride semiconductor device 2 can have a low on-resistance. Also, defects in the body region 113 below the source region 116 are less than when the source region 116 is formed using the ion implantation technique. For example, a defect density of the body region 113 is reduced to 1×10¹⁶ cm⁻³ or less. Therefore, an increase in leakage current and a decrease in breakdown voltage due to defects are improved. (2) In the above-described manufacturing method, the source region 116 is formed between the body contact region 115 and the source electrode 124. The body contact region 115 is not in contact with the source electrode 124. In the conventional techniques, a metal electrode with a large work function (nickel, gold, and the like) is often interposed between the body contact region 115 and the source electrode 124 in order to make ohmic contact between the p-type body contact region 115 and the metal source electrode 124. The nitride semiconductor device 2 does not require such a metal electrode. (3) In the above-described manufacturing method, the body region 113 is formed using an ion implantation technique. Alternatively, a trench may be formed in a predetermined region of the drift region 112, and the body region 113 may be deposited in the trench using a deposition technique. In this case, hydrogen contained in the body region 113 during the deposition of the body region 113 can be released when the above-described activation annealing treatment is performed. Further, in the above-described manufacturing method, the source region 116 is formed after performing the activation annealing treatment. Therefore, in the manufacturing method in which the formation method of the body region 113 is changed to the deposition method, since the source region 116 is not present on the surface of the body region 113 during the activation annealing treatment, hydrogen can be effectively removed from the body region 113. As a result, the body region 113 can have a high activation rate.

Although specific examples of the present disclosure have been described in detail above, these are merely examples and do not limit the scope of claims. The techniques described in the claims include various modifications and modifications of the specific examples illustrated above. In addition, the technical elements described in the present specification or the drawings exhibit technical usefulness alone or in various combinations, and are not limited to the combinations described in the claims at the time of filing. In addition, the techniques illustrated in the present specification or the drawings can achieve multiple purposes at the same time, and achieving one of the purposes itself has technical usefulness.

What is claimed is:

1. A nitride semiconductor device comprising:
a drift region of a first conductivity type that is made of a nitride semiconductor;
a body region of a second conductivity type that is made of a nitride semiconductor and is disposed on the drift region;
a source region of the first conductivity type that is separated from the drift region by the body region;
an insulated gate that faces a portion of the body region that is located between the drift region and the source region; and
a source electrode that is electrically connected to the body region and the source region, wherein
the source region is made of a deposited film.

2. The nitride semiconductor device according to claim 1, wherein
the source region has a carrier concentration of 1×10¹⁹ cm⁻³ or higher.

3. The nitride semiconductor device according to claim 2, wherein
the source region is made of indium tin oxide.

4. The nitride semiconductor device according to claim 2, wherein
the source region is interposed between the body region and the source electrode.

5. The nitride semiconductor device according to claim 1, wherein
the body region has a hydrogen concentration of 1×10¹⁸ cm⁻³ or less.

6. A manufacturing method of a nitride semiconductor device, comprising:
depositing a body region on a drift region, the drift region having a first conductivity type and made of a nitride semiconductor, the body region having a second conductivity type and made of a nitride semiconductor;
releasing hydrogen from the body region by performing a dehydrogenation annealing treatment;
depositing a source region of the first conductivity type on the body region after the releasing of hydrogen from the body region;
forming an insulated gate to face a portion of the body region that is located between the drift region and the source region; and
forming a source electrode that is electrically connected to the body region and the source region.

7. The manufacturing method according to claim 6, wherein
the depositing the source region includes deposing the source region so as to have a carrier concentration of 1×10¹⁹ cm⁻³ or higher.

8. The manufacturing method according to claim 7, wherein
the depositing the source region includes forming the source region from indium tin oxide.

9. The manufacturing method according to claim 7, wherein
the depositing the source region includes depositing the source region so as to be interposed between the body region and the source electrode.

10. The manufacturing method according to claim 6, wherein
the depositing the body region includes deposing the body region so as to have a hydrogen concentration of 1×10¹⁸ cm⁻³ or less.
